(19) United States
(12) Patent Application Publication
(10) Pub. No.: US 2013/0003434 A1
(43) Pub. Date: Jan. 3, 2013

(54) METHOD FOR OPERATING A SEMICONDUCTOR STRUCTURE

(75) Inventors: Hang-Ting Lue, Zhubei City (TW); Chih-Ping Chen, Tainan City (TW)

(73) Assignee: MACRONIX INTERNATIONAL CO., LTD., Hsinchu (TW)

(21) Appl. No.: 13/612,658

(22) Filed: Sep. 12, 2012

Related U.S. Application Data
(63) Continuation-in-part of application No. 13/008,410, filed on Jan. 18, 2011.

(30) Foreign Application Priority Data
Jan. 17, 2012 (TW) 101101844

(51) Int. Cl. G11C 5/02

(52) U.S. Cl. 365/51

(57) ABSTRACT

A method for operating a semiconductor structure is provided. The semiconductor structure comprises a substrate, a first stacked structure, a dielectric element, a conductive line, a first conductive island and a second conductive island. The first stacked structure is formed on the substrate. The first stacked structure comprises first conductive strips and first insulating strips stacked alternately. The first conductive strips are separated from each other by the first insulating strips. The dielectric element is formed on the first stacked structure. The conductive line is formed on the dielectric element. The first conductive island and the second conductive island on opposite sidewalls of the first stacked structure are separated from each other. The method for operating the semiconductor structure comprises respectively applying a first voltage to the first conductive island and applying a second voltage to the second conductive island.

This is a continuation-in-part application of U.S. application Ser. No. 13/008,410, filed Jan. 18, 2011. This application claims the benefit of Taiwan application Serial No. 101101844, filed Jan. 17, 2012. The subject matter of which is incorporated herein by reference.

### BACKGROUND

1. Technical Field

The disclosure relates in general to a method for operating a semiconductor structure and more particularly to a method for operating a memory device.

2. Description of the Related Art

Memory devices are used in storage elements for many products such as MP3 players, digital cameras, computer files, etc. As the application increases, the demand for the memory device focuses on small size and large memory capacity. For satisfying the requirement, a memory having a high element density is need.

The critical dimension of the memory device has been decreased to the ultimate in the art. Thus, designers develop a method for improving a memory device density, using 3D stack memory device so as to increase a memory capacity and a cost per cell. However, a process for manufacturing this kind of the memory device, having a complicated structure, is complicated. In addition, an operating method is limited due to a design limitation.

### SUMMARY

A method for operating a semiconductor structure is provided. The semiconductor structure comprises a substrate, a first stacked structure, a dielectric element, a conductive line, a first conductive island and a second conductive island. The first stacked structure is formed on the substrate. The first stacked structure comprises first conductive strips and first insulating strips stacked alternately. The first conductive strips are separated from each other by the first insulating strips. The dielectric element is formed on the first stacked structure. The conductive line is formed on the dielectric element. The conductive line is extended in a direction perpendicular to a direction which the first stacked structure is extended in. The first conductive island and the second conductive island are formed on the dielectric element. The first conductive island and the second conductive island on opposite sidewalls of the first stacked structure are separated from each other. The method for operating the semiconductor structure comprises respectively applying a first voltage to the first conductive island and applying a second voltage to the second conductive island.

The following description is made with reference to the accompanying drawings.

### BRIEF DESCRIPTION OF THE DRAWINGS

FIGS. 1 to 9 illustrate a process for manufacturing a semiconductor structure in one embodiment.

FIG. 10 illustrates a three dimensional view of a semiconductor structure in one embodiment.

FIG. 11 shows a three dimensional view of a semiconductor structure in one embodiment.

FIG. 12 illustrates a top view of the semiconductor structure in one embodiment.

FIG. 13 illustrates Id-V_{SSL} curves of the semiconductor structure.

FIG. 14 illustrates Vt-V_{inhibit} curves of the semiconductor structure.

FIG. 15 shows program inhibit characteristics of the semiconductor structure.

FIG. 16A shows Vt-programming pulse/shot curves of the semiconductor structure.

FIG. 16B shows Vt-V_{inhibit} curves of the semiconductor structure.

FIG. 16C shows Vt-V_{SSL} curves of the semiconductor structure.

FIG. 17 shows Id-Vg curves of the semiconductor structure.

FIG. 18 shows bit-count-S.S curves of the semiconductor structure.

FIG. 19 shows bit-count-Vt curves of the semiconductor structure.

FIG. 20 shows SEM results of the semiconductor structure.

### DETAILED DESCRIPTION

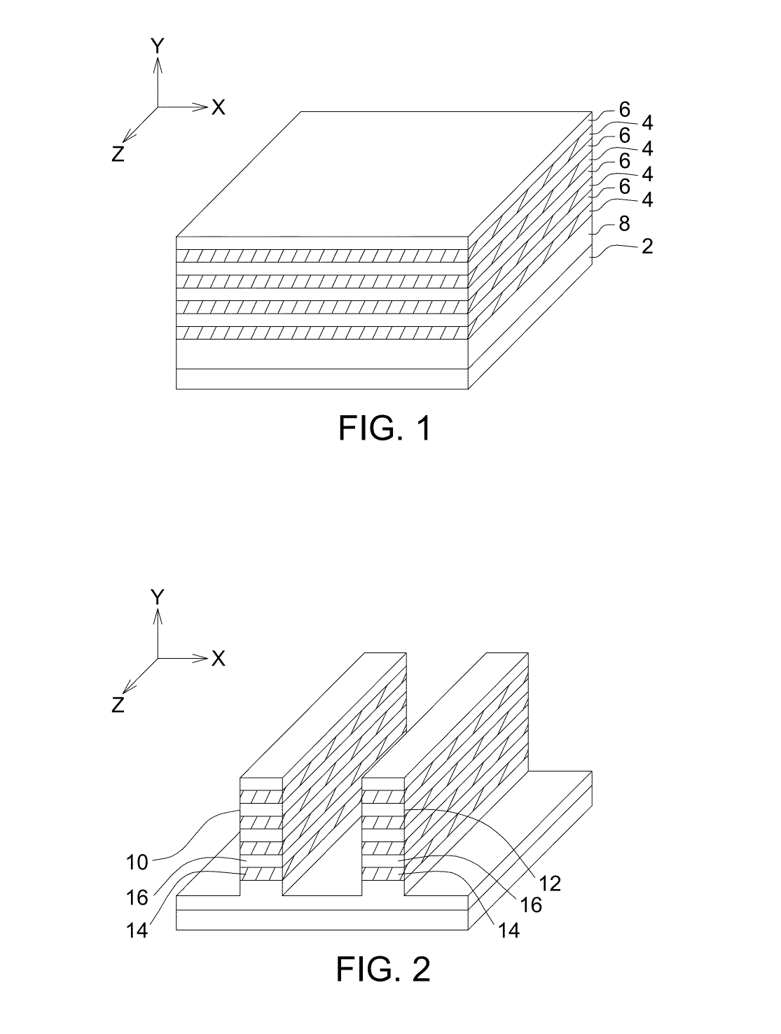

FIGS. 1 to 9 illustrate a process for manufacturing a semiconductor structure in one embodiment. Referring to FIG. 1, conductive layers 4 and insulating layers 6 are alternately stacked on a substrate 2. The conductive layers 4 are separated from each other by the insulating layers 6. The conductive layers 4 include polysilicon. In one embodiment, the conductive layers 4 may be annealed after dopping. The conductive layers 4 may also comprise a metal. The insulating layers 6 include an oxide. The substrate 2 has a buried oxide layer 8 thereon. The conductive layers 4 and the and the insulating layers 6 are patterned for forming stacked structures 10, 12 as shown in FIG. 2. The patterning method comprises a photolithography process. The stacked structures 10 and 12 each comprise alternately-stacked conductive strips 14 and insulating strips 16.

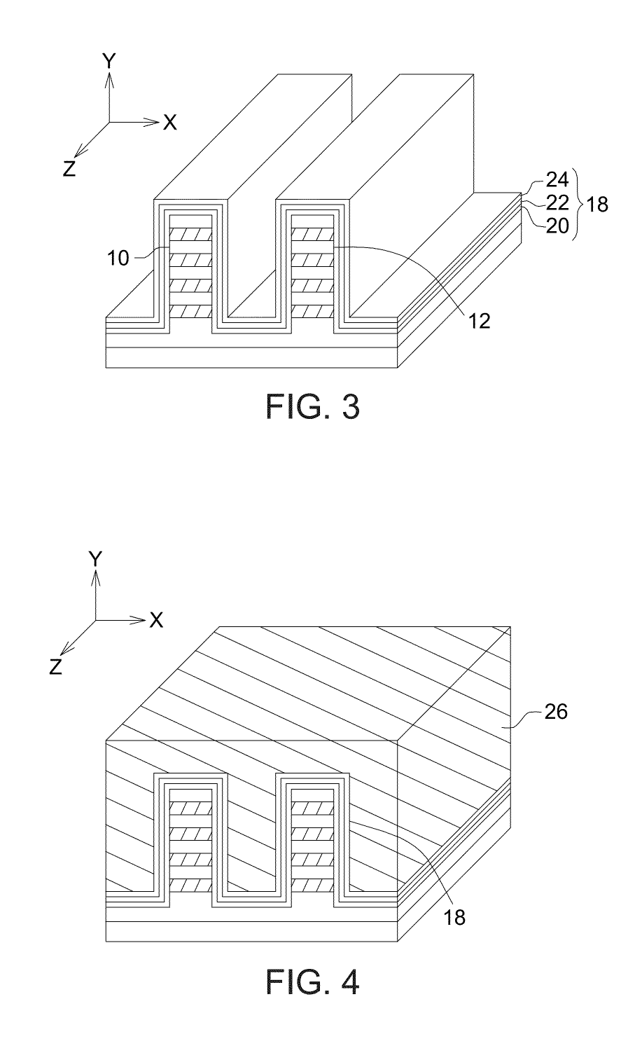

Referring to FIG. 3, a dielectric element 18 is formed on the stacked structures 10 and 12. For example, the dielectric element 18 has a multi-layers structure, for example, comprising dielectric layers 20, 22, 24. In one embodiment, the dielectric layer 20 is a silicon oxide, the dielectric layer 22 is a silicon nitride, and the dielectric layer 24 is a silicon oxide. In other embodiments, the dielectric element 18 is a single-layer dielectric material (not shown), comprising a silicon nitride, or a silicon oxide such as silicon oxide or silicon oxynitride.

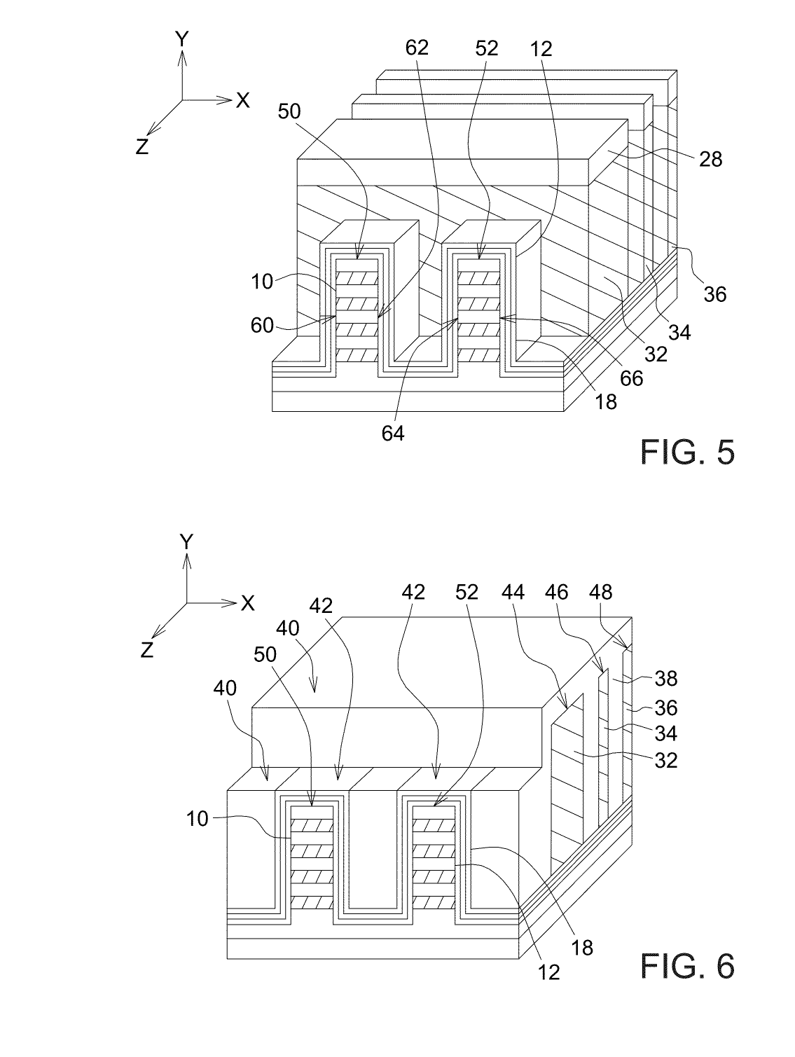

Referring to FIG. 4, a conductive layer 26 is formed on the dielectric element 18. The conductive layer 26 comprises polysilicon. The conductive layer 26 may also comprise a metal. A patterned mask layer 28 is formed on the conductive layer 26. In addition, a portion of the conductive layer 26 not covered by the patterned mask layer 28 is removed for forming conductive lines 32, 34, 36 as shown in FIG. 5. For example, the method for pattering comprises a photolithography process. In embodiments, in an etching process, the conductive layer 26 (such as a polysilicon) (FIG. 4) is etched, and the dielectric element 18 (such an ONO structure) is not etched since the process has an appropriate etching selectivity to the conductive layer 26 and the dielectric element 18.

Referring to FIG. 5, the conductive lines 32, 34, 36 are disposed on the sidewalls 60, 62, 64, 66 and the upper surfaces 50, 52 of the stacked structures 10, 12. The conductive lines 32, 34, 36 are extended in a direction (X-direction) perpendicular to a direction (Z-direction) which the stacked structures 10, 12 is extended in. The patterned mask layer 28 is removed.

Referring to FIG. 6, a dielectric layer 38 is formed on the dielectric element 18 and the conductive lines 32, 34, 36. For example, the dielectric layer 38 comprises a silicon oxide which may be formed by a deposition for a mixture vapor comprising silane and ozone, or TEOS and ozone/oxygen. The dielectric layer 38 has a flat upper surface 40. In embodiments, the upper surface 40 is aligned with or higher than the upper surface 42 of the dielectric element 18 and the upper surfaces 44, 46, 48 of the conductive lines 32, 34, 36 on the upper surfaces 50, 52 of the stacked structures 10, 12. The dielectric layer 38 having the flat upper surface 40 helps performance for a later photolithography process such as an exposing step.

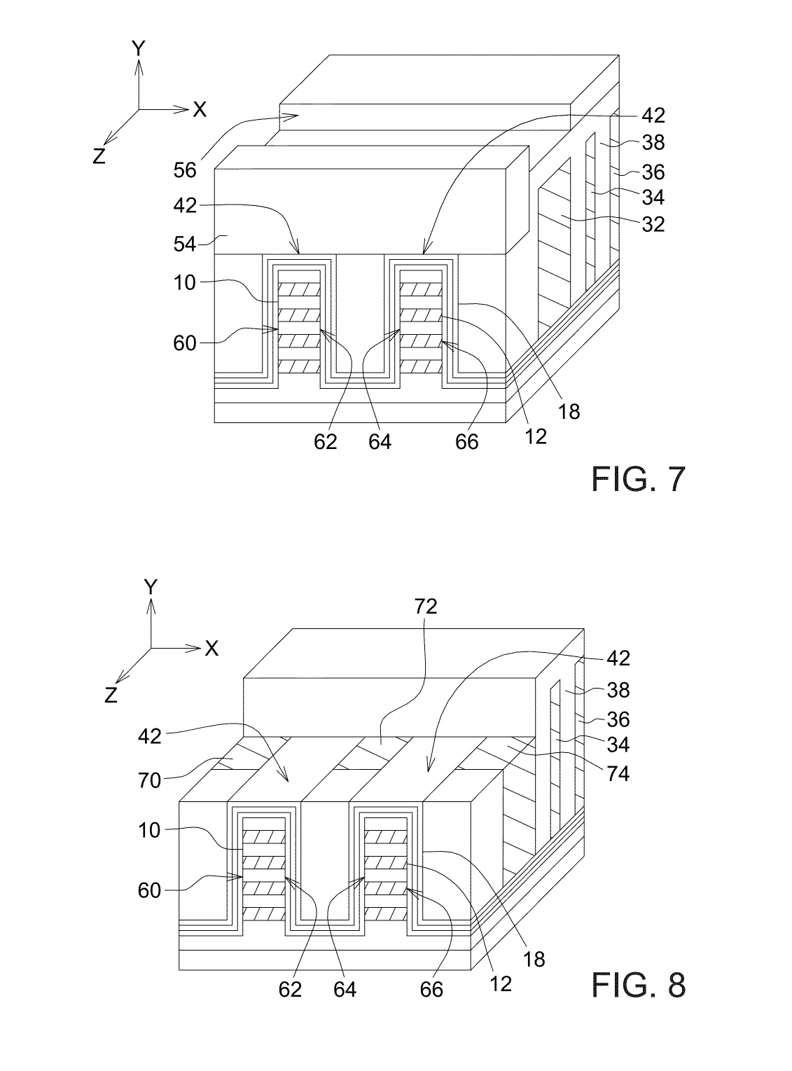

Referring to FIG. 7, a patterned mask layer 54 is formed on the dielectric layer 38. For example, the patterning method comprises a photolithography process. The patterned mask layer 54 has an opening 56 exposing the dielectric layer 38 on the conductive line 32. The dielectric layer 38 and the conductive line 32 exposed by the opening 56 is removed until the upper surface 42 of the dielectric element 18 is exposed, remaining a portion of the conductive line 32 on the opposite sidewalls 60, 62, 64, 66 of the stacked structures 10, 12 for forming conductive islands 70, 72, 74 as shown in FIG. 8. In embodiments, in an etching process, the dielectric layer 38 (such as a TEOS oxide) and the conductive line 32 (such as a polysilicon) (FIG. 7) is etched, and the dielectric element 18 (such an ONO structure) is not etched since the process has an appropriate etching selectivity to the conductive line 32, the dielectric element 18, and the dielectric layer 38. In other words, the conductive islands 70, 72, 74 are self-aligned. Therefore, the manufacturing process is simple. In other embodiments, the conductive lines 34, 36 can be properly patterned for forming other conductive islands (not shown) according to designs. The patterned mask layer 54 (FIG. 7) is removed.

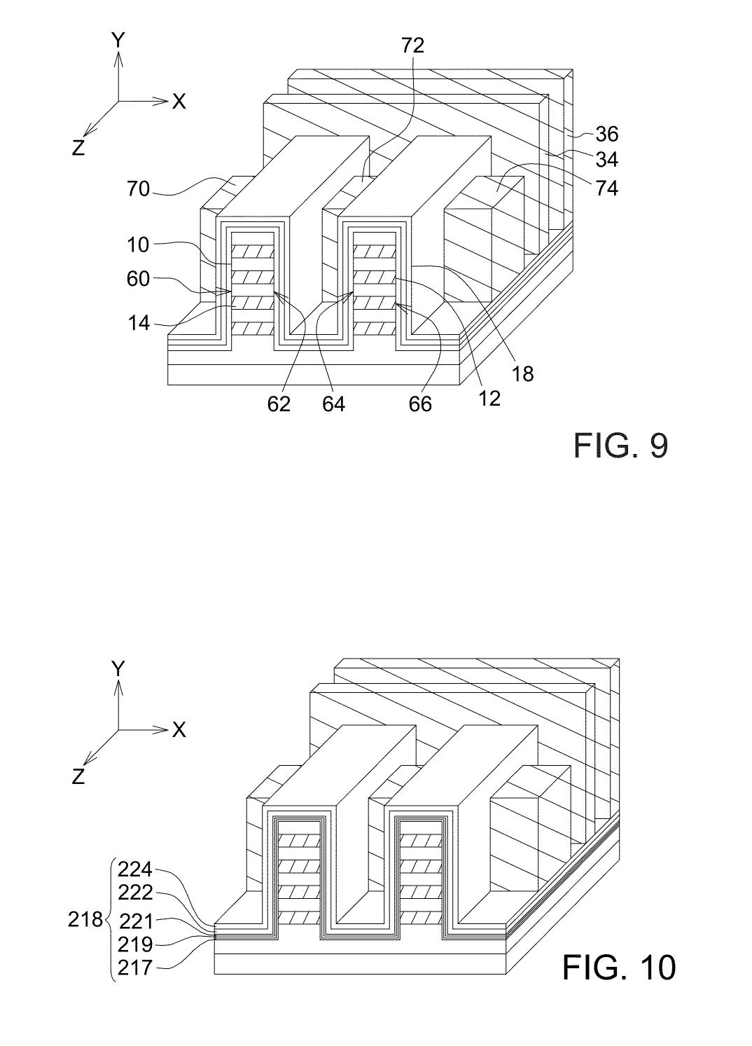

FIG. 9 does not show the dielectric layer 38 in FIG. 8. Referring to FIG. 9, the conductive islands 70 and 72 on the opposite sidewalls 60 and 62 of the stacked structure 10 are separated from each other. In addition, the conductive islands 72 and 74 on the opposite sidewalls 64 and 66 of the stacked structure 12 are separated from each other. The conductive islands 70, 72, 74 are arranged in a direction (X-direction) perpendicular to the direction (Z-direction) which the stacked structures 10, 12 are extended in.

Referring to FIG. 9, the dielectric element 18 is disposed between the stacked structures 10, 12 and the conductive lines 34, 36, and disposed between the stacked structures 10, 12 and the conductive islands 70, 72, 74. In one embodiment, the conductive lines 34, 36 and the conductive islands 70, 72, 74 have a first type conductivity. The conductive strips 14 have a second type conductivity opposite to the first type conductivity. For example, the first type conductivity is a n-type conductivity, and the second type conductivity is a p-type conductivity. The conductive islands 70, 72, 74 may be constructed of a single material or constructed of composite materials.

The semiconductor structure manufactured by the method according to embodiments can have exact features. For example, in embodiments, the half pitch of the WL is 37.5 nm. The etching critical dimension (ECD) of the WL is about 25 nm. The ECD of the bit line (BL) is about 30 nm. The channel length of the SSL and the GSL is about 0.25 um, which is long enough to avoid punch-through effect well, satisfying program-inhibit demand. In addition, the independently controlled double gate (IDG) decoded 3D vertical gate (VG) device in embodiments has an array layout similar to an array layout of a conventional NAND device. Since the IDG SSL is formed by a self-aligned method and the pitch of which is scalable, it does not require additional area.

FIG. 10 shows a three dimensional view of a semiconductor structure in one embodiment. The semiconductor structure shown in FIG. 10 is different from the semiconductor structure shown in FIG. 9 in that the semiconductor structure shown in FIG. 10 has a BE-SONOS element (referring U.S. Pat. No. 7,529,137, for example). Referring to FIG. 10, the dielectric element 218 has a multi-layers structure, comprising the dielectric layers 217, 219, 221, 222, 224. In embodiments, the thicknesses of the dielectric layers 217, 219, 221 are smaller than the thicknesses of the dielectric layers 222, 224. The dielectric layers 217, 221, 224 may be silicon oxide. The dielectric layers 219, 222 may be silicon nitride.

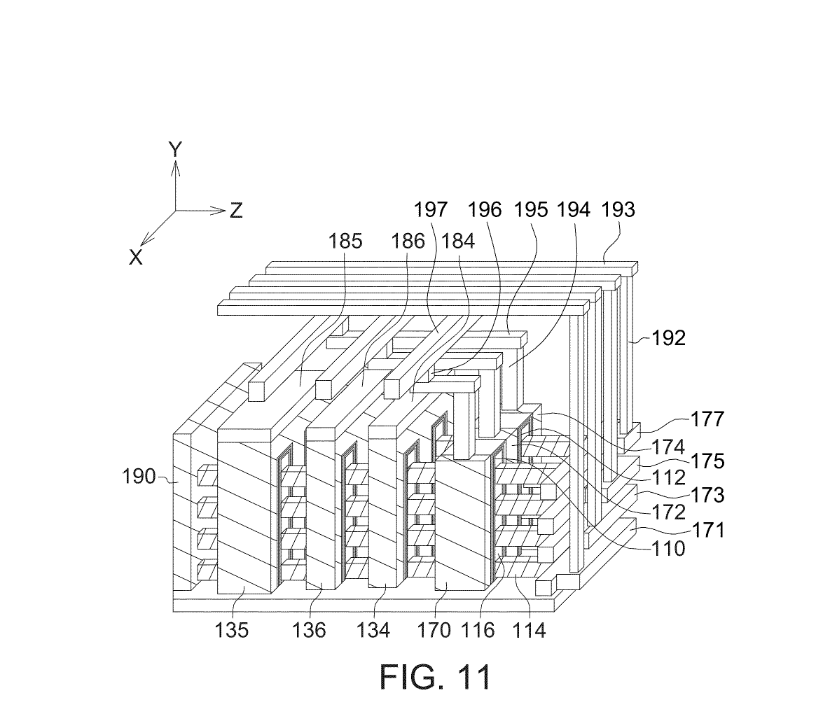

FIG. 11 illustrates a three dimensional view of a semiconductor structure in one embodiment. FIG. 11 does not shown a dielectric layer, as the dielectric layer 38 shown in FIG. 8, and a portion of the insulating strip 116 between the conductive islands 110, 112 and the conductive lines 134, 135, 136 (namely, the insulating strips 116 are as continuous as the conductive strips 114) of the semiconductor structure.

Referring to FIG. 11, in embodiments, the semiconductor structure is a 3D vertical gate memory device, for example, comprising a NAND flash memory and an anti-fuse memory, etc. Metal silicide layers 184, 185, 186 may be formed on the conductive lines 134, 135, 136. For example, the metal silicide layers 184, 185, 186 comprise tungsten silicide, cobalt silicide, or titanium salicide. The conductive strips 114 of different layers act as bit lines (BL) of memory cells of different planes. For example, the conductive strip 114 of the most bottom layer is defined as the 1st layer BL. The 1st layer BLs of different rows are electrically connected to the common conductive layer 171. The conductive layer may be the first layer conductive layer (1st layer CO).

The conductive strips 114 upper than the conductive strip 114 of the most bottom layer are defined as the 2nd layer BL, the 3rd layer BL, the 4th layer BL in order. The 2nd layer BLs of different rows are electrically connected to the common conductive layer 173. The 3rd layer BLs of different rows are electrically connected to the common conductive layer 175. The 4th layer BLs of different rows are electrically connected to the common conductive layer 177. The conductive layer 173, the conductive layer 175 and the conductive layer 177 may be respectively the 2nd layer CO, the 3rd layer CO, and the 4th layer CO. The conductive layer 171, the conductive layer 173, the conductive layer 175 and the conductive layer 177 are electrically connected to the conductive via 192 and the conductive layer 193 of different rows. The conductive strips and the conductive layers of upper layers (not shown) are analogous thereto. The conductive layer 171, the conductive layer 173, the conductive layer 175, the conductive layer 177, the conductive via 192 and the conductive layer 193 may have a double pitch for better process window.

The conductive strips 114 are coupled with a common source line 190. The common source line 190 may comprises polysilicon. The conductive line 135 acts as a ground selection line (GSL). The conductive lines 134 and 136 act as word lines (WL). For example, the conductive line 136, which is most close to the conductive line 135 (GSL), of the conductive lines is defined as the WL0. The conductive line 134 far from the conductive line 135 (GSL) and next to the conductive line 136 is defined as the WL1. The conductive lines (not shown) more far from the conductive line 135 (GSL) than the conductive line 134 is defined as the WL2, the WL3, and so forth.

The conductive islands 170, 172, 174 are independent electrically connected to the conductive via 194, the conductive layer 195, the conductive via 196 and the conductive layer 197 of different groups, to electrically connected to the decoding circuit (parallel to the word line). For example, the conductive island 170, the conductive island 172 and the conductive island 174 in FIG. 11 are respectively defined as the SSL0, the SSL1 and the SSL2, and so forth.

The material for the conductive via 192, the conductive layer 193, the conductive via 194, the conductive layer 195, the conductive via 196 and the conductive layer 197 may be a metal. For example, the conductive layer 195 is the ML1, the conductive layer 197 is the ML2, the conductive layer 193 is the ML3, and so forth. The conductive via 196 may also be indicated by the mark V11.

Referring to FIG. 11, the conductive islands 170, 172 and 174 separated from each other are applied voltages individually. Therefore, the conductive strips 114 (BL) in different stacked structures 110 and 112 are selected or unselected individually. Thus, the semiconductor structure can be used by various operating methods. This semiconductor structure is the IDG decoded VG device. In one embodiment, this memory device is a double-gate TFT BE-SONOS device.

In one embodiment, for example, when the conductive strip 114 (BL) between the conductive island 170 (SSL0) and the conductive island 172 (SSL1) is selected to be turned on, a positive bias (V_{SSL}) is applied to the conductive island 170 and the conductive island 172 for turning on the conductive strip 114. When the conductive strip 114 (BL) between the conductive island 172 (SSL1) and the conductive island 174 (SSL2) is unselected, a positive bias is applied to the conductive island 172 and a negative bias is applied to the conductive island 174 for turning off the conductive strip 114. The foregoing positive bias may be about +2V˜+4V. The foregoing negative bias may be about −2V˜−8V. For example, in one embodiment, the positive bias is about +3.3 V, and the negative bias is about −3.3 V. In another embodiment, the positive bias is about +2.5 V, and the negative bias is about −7 V. In yet another embodiment, the positive bias is about +2 V, and the negative bias is about −7 V. A far SSL is turned off by applying 0 V or grounding.

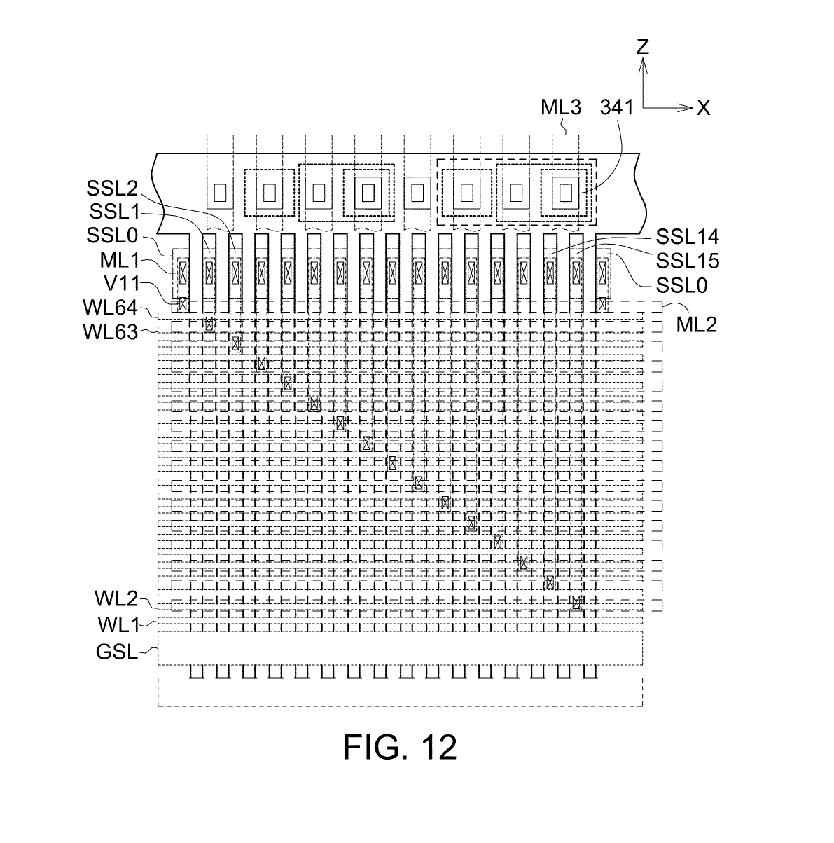

FIG. 12 illustrates a top view of the semiconductor structure having 8 layers of the conductive strips (BLs) in one embodiment. The conductive strips (BLs) of different layers are respectively electrically connected to the conductive structures of 8 groups. The conductive structure having a stair shape may be formed by the conductive layer 171, the conductive via 192 and the conductive layer 193 shown in FIG. 11, or formed by the conductive layer 173, the conductive via 192 and the conductive layer 193 shown in FIG. 11, and so forth. As shown in FIG. 12, the ML3s of the different groups of the stair case conductive structures are electrically connected to the respective pads 341. In this case, the semiconductor structure has 64 word lines WL1, WL2 . . . WL63, and WL64.

Referring to FIG. 12, the semiconductor structure in this case has 16 SSLs in one period. The conductive islands SSL0, SSL1, SSL2 . . . SSL14 and SSL15 are respectively electrically connected to the first metal line ML1, the conductive via V11 and the second metal line of different groups (16 groups). The second metal line ML2 is electrically connected to the SSL decoding circuit. In embodiments, the semiconductor structure of another period is repeated along X direction. In addition, the semiconductor structures of two adjacent periods may use the common conductive island SSL0.

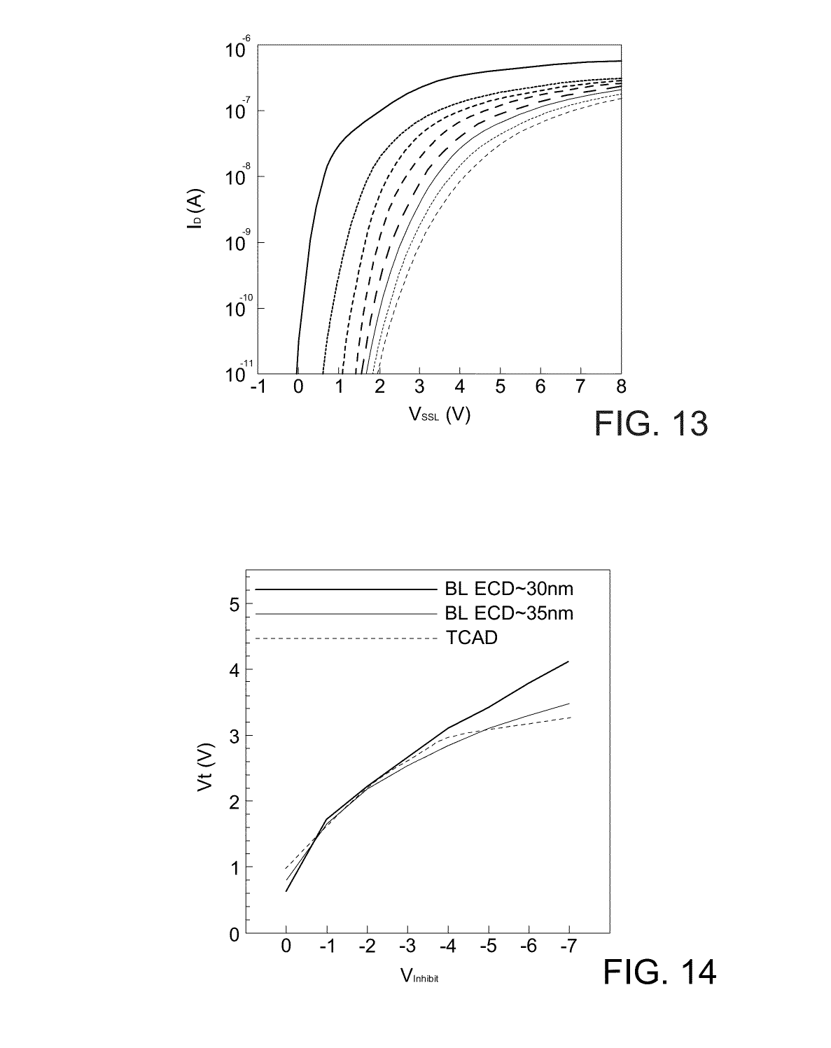

FIG. 13 illustrates Id-V_{SSL} curves of the semiconductor structure having the BL of the ECD of about 30 nm. One gate is V_{SSL}, and the others are V_{inhibit} of about −1V˜−7V (the more right the curve is, the more negative the V_{inhibit} is). From FIG. 13, it is found that as the V_{inhibit} is more negative, the Vt is more high. In addition, as the V_{inhibit} for turning off the SSL channel is about −1V˜−7V, the V_{SSL} for turning on the SSL channel is higher than about +2V preferably. For example, V_{SSL}+2V, and V_{inhibit}=−7V provides a correct ON/OFF requirement for the selected/unselected channel BLs.

FIG. 14 illustrates Vt-V_{inhibit} curves of the semiconductor structure. From FIG. 14, it is observed that as the size of the BL ECD is smaller, the Vt of the semiconductor structure is larger, and the reason of which is supposed that the element of small width results in easy depletion. The TCAD simulation curve is consistent with experimental results.

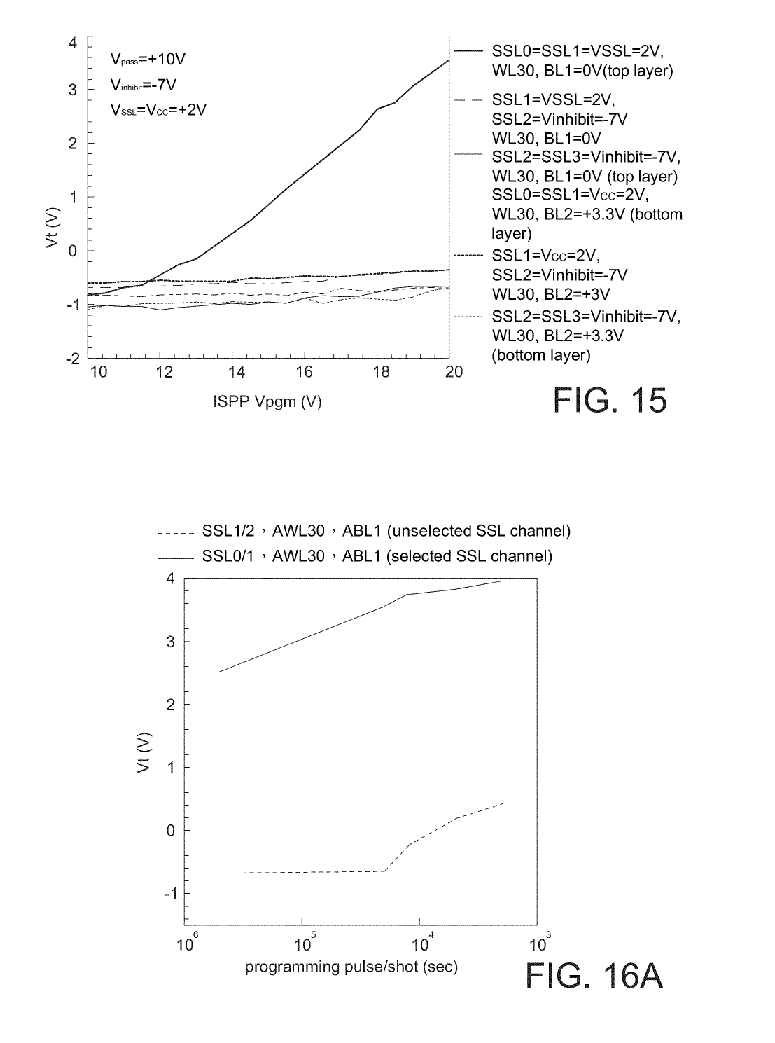

The semiconductor structure in embodiments provides not only read inhibit but also program inhibit. FIG. 15 shows program inhibit characteristics of the semiconductor structure. The BL between the SSL0 and the SSL1 is selected and turned on by applying the V_{SSL} of +2V to the SSL0 and the SSL1. The selected BL is 0V. The unselected BLs are turned off by applying the V_{inhibit} of −7V to the other SSLs. The unselected BL is +3.3V. During the ISPP process, in which one-shot program time is 50 usec, the pass-gate voltage (VPASS) is 10V. The results shows that the semiconductor structure has excellent program inhibit characteristics.

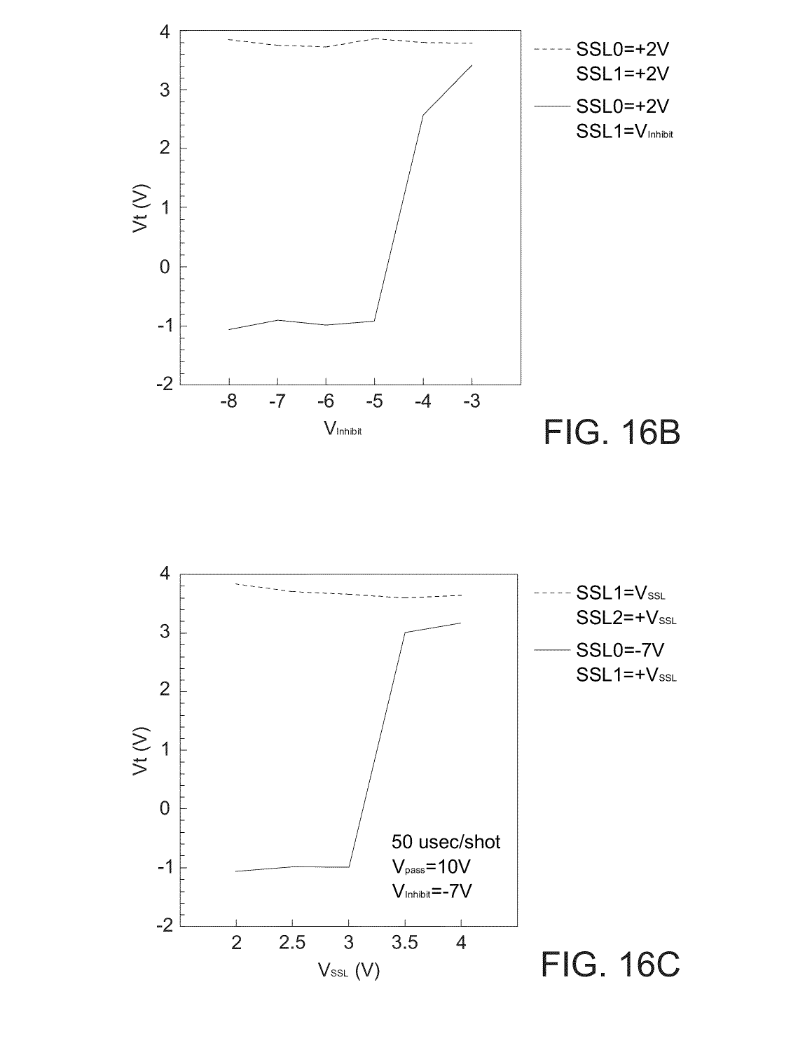

FIG. 16A shows that the program disturb is small, even when the programming pulse time is increased to 100 usec for each ISPP shot. This suggests that the semiconductor structure has good punch-through immunity that suppresses the leakage when channel potential is boosted high (about 8V). FIG. 16B shows that as the V_{SSL} is +2V, the V_{inhibit} greater than −5V is necessary for good inhibit performance. FIG. 16C shows that as the V_{inhibit} is 7V, the V_{SSL} smaller than 3V is necessary for good inhibit performance.

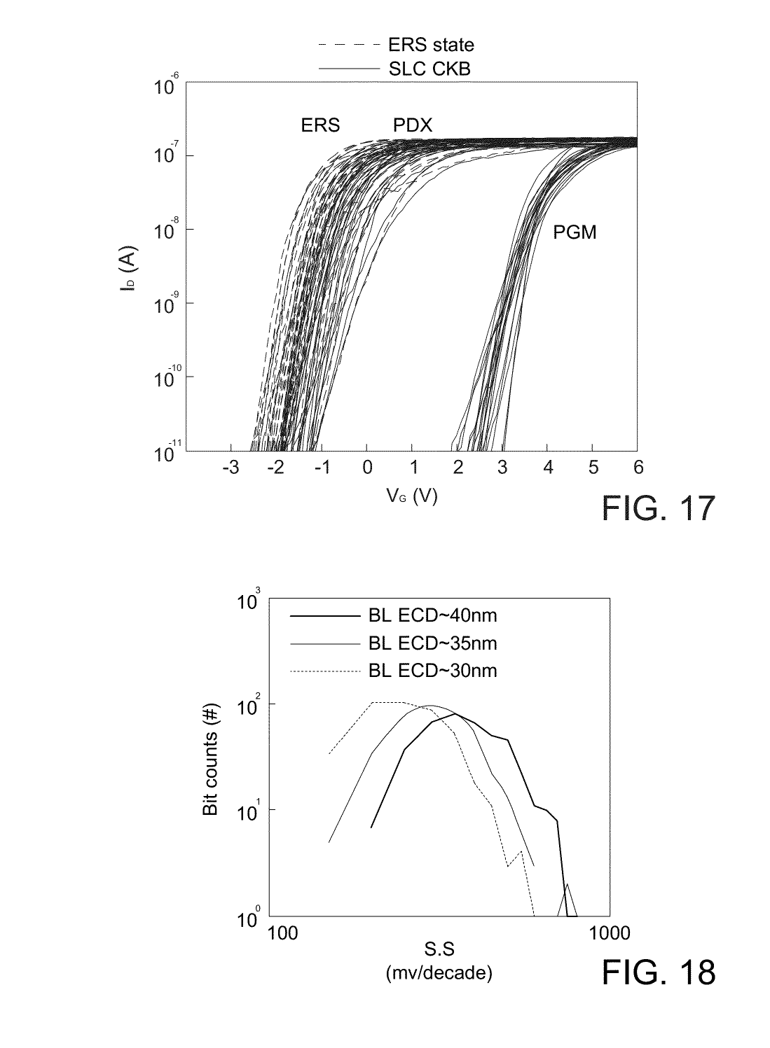

FIG. 17 shows Id-Vg characteristics during erasing the 3DVG TFT device of 3Xnm with SLC CKB operation. The device has 2 layers of BL and 64-WL NAND. The Idsat may be larger than 150 nA. The Vt may be defined at 20 nA˜40 nA. FIG. 17 shows that the semiconductor structure has excellent subthreshold behavior, owing to the good gate control capability of a narrow-width double-gate device. The 64-WL NAND having the Idsat greater than 150 nA can provide well memory sensing effect.

FIG. 18 shows that as the 3Xnm 3DVG TFT device has the BL of narrow ECD, it has good subthreshold slope (S.S.) distribution. The S.S. is 200 mV/decade 500 mV/decade, and has a narrow distribution, owing to the smaller poly silicon bulk trap volume.

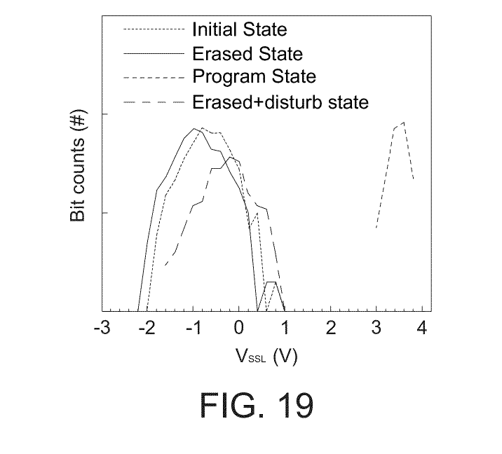

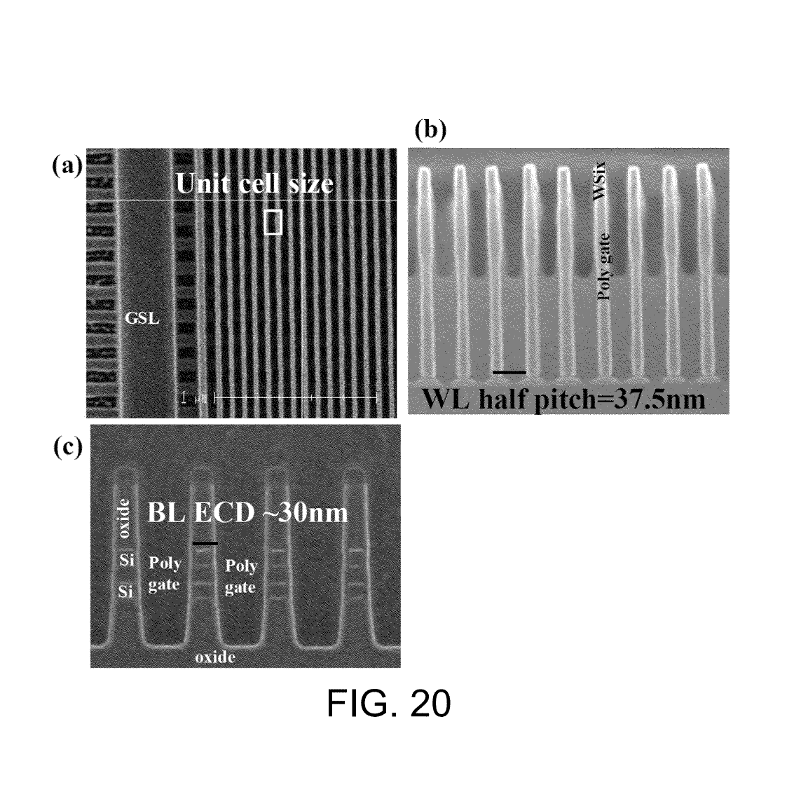

FIG. 19 shows Vt distributions of the 3Xnm 3DVG TFT device at the initial, the erased, and the programmed states after a SLC checkerboard (CKB) programming. The memory window is well separated after program-disturb stressing, it shows reasonable good performances for the device in embodiments.

FIG. 20 shows SEM results of the semiconductor structure. The SEM picture indicated with (a) shows a top view of an array of the semiconductor structure. The SEM picture indicated with (b) shows a cross-section view of the WL, in which the half pitch of the WL is 37.5 nm and an ECD of the WL is about 25 nm. The SEM picture indicated with (c) shows an ECD of the BL is about 30 nm, and BE-SONOS ONO are deposited on the two opposite sidewalls of the BL.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for operating a semiconductor structure, wherein, the semiconductor structure comprises:
a substrate;
a first stacked structure formed on the substrate, wherein the first stacked structure comprises first conductive strips and first insulating strips stacked alternately, the first conductive strips are separated from each other by the first insulating strips;
a dielectric element formed on the first stacked structure;
a conductive line formed on the dielectric element, wherein the conductive line is extended in a direction perpendicular to a direction which the first stacked structure is extended in; and
a first conductive island and a second conductive island formed on the dielectric element, wherein the first conductive island and the second conductive island on opposite sidewalls of the first stacked structure are separated from each other,
the method for operating the semiconductor structure comprising:
respectively applying a first voltage to the first conductive island and applying a second voltage to the second conductive island.

2. The method for operating the semiconductor structure according to claim 1, wherein the first voltage and the second voltage are both positive biases.

3. The method for operating the semiconductor structure according to claim 2, wherein the first conductive strip is selected by the operating method.

4. The method for operating the semiconductor structure according to claim 3, wherein the selected first conductive strip is turned on.

5. The method for operating the semiconductor structure according to claim 1, wherein the first voltage is a positive bias, the second voltage is a negative bias.

6. The method for operating the semiconductor structure according to claim 5, wherein the first conductive strip of the first stacked structure is unselected by the operating method.

7. The method for operating the semiconductor structure according to claim 6, wherein the unselected first conductive strip is turned off.

8. The method for operating the semiconductor structure according to claim 1, wherein the semiconductor structure further comprises:
a second stacked structure formed on the substrate, wherein the second stacked structure comprises second conductive strips and second insulating strips stacked alternately, the second conductive strips are separated from each other by the second insulating strips, wherein the dielectric element is formed on the second stacked structure, the conductive line is extended in the direction perpendicular to a direction which the second stacked structure is extended in; and
a third conductive island formed on the dielectric element, wherein the second conductive island and the third conductive island on opposite sidewalls of the second stacked structure are separated from each other,
the method for operating the semiconductor structure further comprising:
applying a third voltage to the third conductive island.

9. The method for operating the semiconductor structure according to claim 8, wherein the first voltage and the second voltage are both positive biases, the third voltage is a negative bias.

10. The method for operating the semiconductor structure according to claim 8, wherein the first conductive strip of the first stacked structure is selected by the operating method.

11. The method for operating the semiconductor structure according to claim 10, wherein the selected first conductive strip is turned on.

12. The method for operating the semiconductor structure according to claim 8, wherein the second conductive strip of the second stacked structure is unselected by the operating method.

13. The method for operating the semiconductor structure according to claim 12, wherein the unselected second conductive strip is turned off.

14. The method for operating the semiconductor structure according to claim 1, wherein the first voltage is +2 V˜+4 V, the second voltage is −2 V˜−8 V.

15. The method for operating the semiconductor structure according to claim 1, wherein the semiconductor structure is a 3D vertical gate memory device.

16. The method for operating the semiconductor structure according to claim 1, wherein the first conductive strip is functioned as a bit line, the first conductive island and the second conductive island are functioned as string selection lines.

17. The method for operating the semiconductor structure according to claim 1, wherein the first conductive island and the second conductive island are arranged in a direction perpendicular to the direction which the first stacked structure is extended in.

18. The method for operating the semiconductor structure according to claim 1, wherein the first conductive island or the second conductive island has a single material.

19. The method for operating the semiconductor structure according to claim 1, wherein the first conductive island or the second conductive island has composite materials.

20. The method for operating the semiconductor structure according to claim 1, wherein the conductive line, the first conductive island and the second conductive island have a first type conductivity, the conductive strip has a second type conductivity opposite to the first type conductivity.
